(19) United States
(12) Patent Application Publication
(10) Pub. No.: US 2003/0096457 A1
(43) Pub. Date: May 22, 2003

(54) Sonic transducers bonded with polymers and methods of making same for efficient sonic energy transfer

(76) Inventors: Douglas A. Gottschalk, Glen Riddle, PA (US); Michael Joseph Hollweck, West Chester, PA (US)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/299,308

(22) Filed: Nov. 19, 2002

Related U.S. Application Data
(60) Provisional application No. 60/337,208, filed on Nov. 19, 2001.

(51) Int. Cl. H01L 21/335

(52) U.S. Cl. 438/142

(57) ABSTRACT

The present invention contemplates methods of bonding devices that produce sonic energy to polymer articles, the bonded articles themselves, methods for fabricating a semiconductor processing apparatus, and the apparatus itself. The present invention provides for an apparatus comprised of polymers, which is not susceptible to corrosion and permit the transmission of sonic energy through the walls of the apparatus. The polymer can be, for example, a fluoropolymer.

This application claims benefit of Provisional Application No. 60/337,208 filed Nov. 19, 2001, the entirety of which is incorporated herein by reference.

### FIELD OF THE INVENTION

The present invention relates generally to methods of bonding sonic transducers to polymer articles in such a manner that the resulting bond can withstand exposures to chemicals and sonic energy, the bonded articles themselves, and more particularly, methods of making semiconductor processing apparatus, and the apparatus themselves.

### BACKGROUND OF THE INVENTION

Polymers are used as protective coatings in many applications because they impart desirable properties to the article coated, e.g., fluoropolymers impart a nonstick coating. However, these same properties also make some polymers difficult to incorporate into fabrication techniques because they do not adhere well to other materials. Conventional fabrication methods that utilize fluoropolymers, for example, include those methods described in U.S. Pat. Nos. 5,996,601, 5,888,850, and 6,261,985 which are herein incorporated by reference in their entireties. The '601 patent describes a method and apparatus for mechanically bonding a polymer to a convex surface of a substrate. The '850 patent provides a method of providing a protective coating for an electronic package. The '985 patent describes high temperature cookware that is made with material that provides beneficial properties.

Metals are conventionally bonded to polymers by immersing the metal in a bath of molten polymer or by spray coating the metal article with molten polymer. Another technique, called rotolining, applies a coating of polymer to an enclosed vessel by spinning the vessel while it contains molten polymer so that a portion of the polymer adheres to the vessel.

Traditional techniques of applying a coating to an article have several disadvantages that are undesirable. For example, when traditional techniques are used to coat a metal article having a complex geometry with a fluoropolymer, the resulting fluoropolymer coating may be susceptible to cracking and have disadvantageous variations in thickness. Conventional techniques may also form an incomplete barrier of protection if the entire surface of the article is not contacted with molten polymer. Defects in protective coatings will expose process equipment to highly corrosive and harmful process solutions that reduce the lifespan of the equipment and increase the cost of manufacturing due to repair and replacement of parts.

Manufacturers, and particularly semiconductor manufacturers, are in need of apparatus that are less susceptible to corrosion and wear while still permitting energy to be transmitted and detected through the walls of the apparatus. Manufacturers try to increase efficient energy transfer through an apparatus by limiting significant energy loss through the walls of the apparatus. Energy loss usually occurs at interfaces between layers of the walls of an apparatus, particularly where an air gap exists.

For example, conventional semiconductor vessel designs employ sonic energy from sonic transducers to enhance wet chemical processing. Sonic transducers are mounted on a metallic wall of a vessel the inside of which has been previously coated with a protective polymer. This structure is susceptible to corrosion, seal failure and/or poor energy transmission due to lack of intimate surface contact between elements. In other cases, crystals that transmit sonic energy are bonded to either quartz or tantallum windows that are mechanically placed in the side or bottom of the vessel chamber. This method is expensive and does not provide a smooth clean single surface in the interior of the vessel.

Conventional techniques used in the design of apparatus having a sonic transducer also include coating sonic transducers with a protective film and disposing them inside of a vessel, on a vessel wall, where they are subjected to processing solutions. These techniques however, expose polymer coatings, transducers, and their electrical connections to corrosive processing liquids. As a result, polymer coating and seal failures lead to the contamination of semiconductor wafers and the failure of equipment.

Further, fabricating an apparatus with materials having different rates of thermal expansion causes gaps between the materials and thereby reduces the efficiency of energy transfer through the walls of the apparatus. Hence, methods which address these needs have long been sought.

### SUMMARY OF THE INVENTION

The present invention contemplates methods of bonding devices that produce sonic energy to polymer articles, the bonded articles themselves, the methods for fabricating a semiconductor processing apparatus, and the apparatus itself. The present invention provides for an apparatus comprised of polymers, which is not susceptible to corrosion and permit the transmission of sonic energy through the walls of the apparatus.

In one general aspect of the present invention, there is provided a method for adhering a sonic device to a polymer. Initially, there is provided a polymer surface that has a bonding portion to which a sonic device will be attached. The bonded portion is chemically treated, with an etching agent to prepare the surface for bonding. Next, the sonic device and the polymer surface are treated with a washing solution. After washing, the sonic device is placed on the etched bonding portion of the polymer surface with an adhesive being disposed between the bonding portion and the sonic device. Pressure may be applied to the sonic device and polymer surface to assure that intimate contact is made between the adhesive and the materials. Lastly, the adhesive is cured to form a bond.

In one embodiment, a metal layer is adhered to the polymer surface and a sonic device is adhered to the metal layer. In some embodiments, the polymer is a fluoropolymer. In some embodiments the polymer is polytetrafluoroethylene, commonly called Teflon®, and the adhesive is an epoxy resin.

In another aspect of the present invention, the method of adhering a sonic device to a polymer includes the step of roughing the surface of the bonding portion to increase its surface area. The roughing step occurs before any adhesive is contacted with the bonding portion.

In another aspect of the present invention, the methods include the step of coating the sonic device and the polymer surface with a thermo-conductive polymer after the adhesive is cured. This is known in the art as potting.

The present invention also includes a semiconductor processing apparatus that include walls comprising a polymer and having a bonded portion, a bottom, at least one sonic energy producing device adhered to the bonded portion, and an adhesive layer disposed between the walls and the device.

The present invention also includes methods of fabricating a semiconductor processing apparatus composed of a polymer. The methods include a first step of fabricating a plurality of walls wherein the semiconductor processing apparatus has one or more bonding portions. Each wall is made by providing a polymer layer. A bonded portion is etched with an etching agent. After etching, a sonic device and the polymer layer are treated with a washing solution. Next, an adhesive is disposed between the bonded portion and the device and the device is disposed on the polymer layer. Pressure may be applied to the sonic device and polymer layer to assure that intimate contact is made between the adhesive and the materials. Then, the adhesive is cured. These steps are repeated as needed to fabricated the number of walls that are needed. Lastly, the walls are fused together to make an apparatus. In some cases the vessel may be a single machined piece.

### BRIEF DESCRIPTION OF THE DRAWINGS

The numerous features and advantages of the present invention are better understood by those skilled in the art by reference to the accompanying detailed description and the following drawings, in which:

FIG. 1 is a flow chart illustrating methods of fabricating polymers articles of the present invention.

FIG. 2a is a cross sectional view of an exemplary polymer article.

FIG. 2b is a cross sectional view of another exemplary polymer article.

FIG. 3 is a flow chart illustrating another method of fabricating polymer articles of the present invention.

FIG. 4 is a flow chart illustrating another method of fabricating polymer articles.

FIG. 5 is a perspective view of an exemplary semiconductor processing apparatus.

FIG. 6 is a cut-away view of an exemplary semiconductor processing apparatus.

FIG. 7 is a cross sectional view of an exemplary semiconductor processing apparatus.

FIG. 8 is a cross sectional view of an exemplary wall.

FIG. 9 is a cross sectional view of another exemplary wall.

FIG. 10 is a flow chart illustrating a method of fabricating a semiconductor processing apparatus.

FIG. 11 is a flow chart illustrating another method of fabricating a semiconductor processing apparatus.

FIG. 12 is a flow chart illustrating another method of fabricating a semiconductor processing apparatus.

FIG. 13 is a flow chart illustrating another method of fabricating a semiconductor processing apparatus.

### DETAILED DESCRIPTION

The present invention includes methods of bonding sonic devices to polymer articles, the bonded articles themselves, methods of fabricating a semiconductor processing apparatus, and the apparatus themselves. The present invention contemplates methods of making polymer articles that have a sonic device bonded to them by an adhesive. The present invention also contemplates methods of fabricating a semiconductor processing apparatus that have polymer walls. The walls have a sonic device bonded to them.

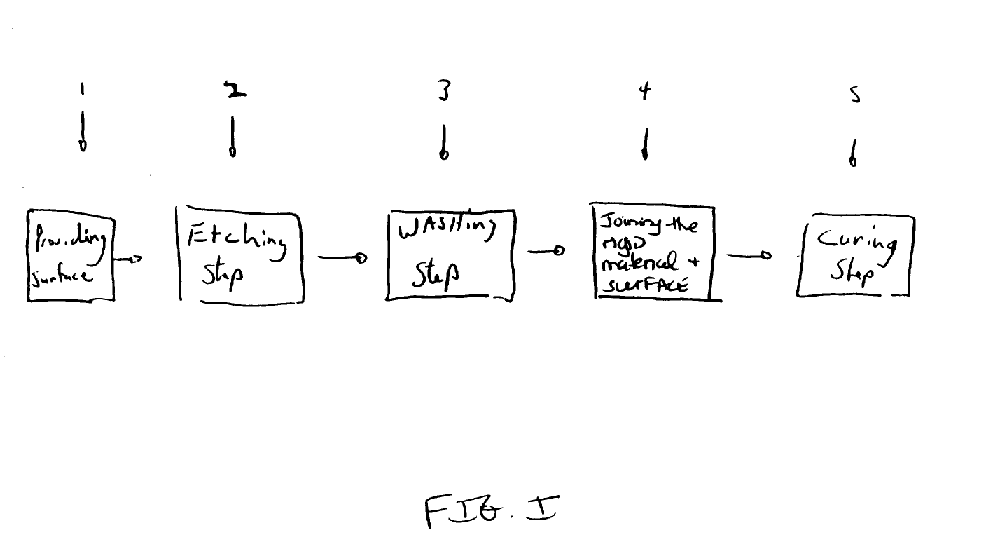

FIG. 1 is a flow chart illustrating methods of fabricating polymer articles of the present invention. Reference numerals 1 through 5 are employed to indicate the steps of one embodiment of the present methods. First, a polymer surface having a bonding portion is provided in step 1. The bonding portion is then chemically treated with an etching agent in step 2. After treatment, the bonded portion and a sonic device are treated with a washing solution in step 3. Then, the sonic device and polymer surface are joined together by disposing an adhesive between them in step 4. Lastly, the adhesive is cured to form a bond between the sonic device and the polymer surface in step 5. In some cases it may be preferable to apply pressure to the sonic device and the polymer surface during curing.

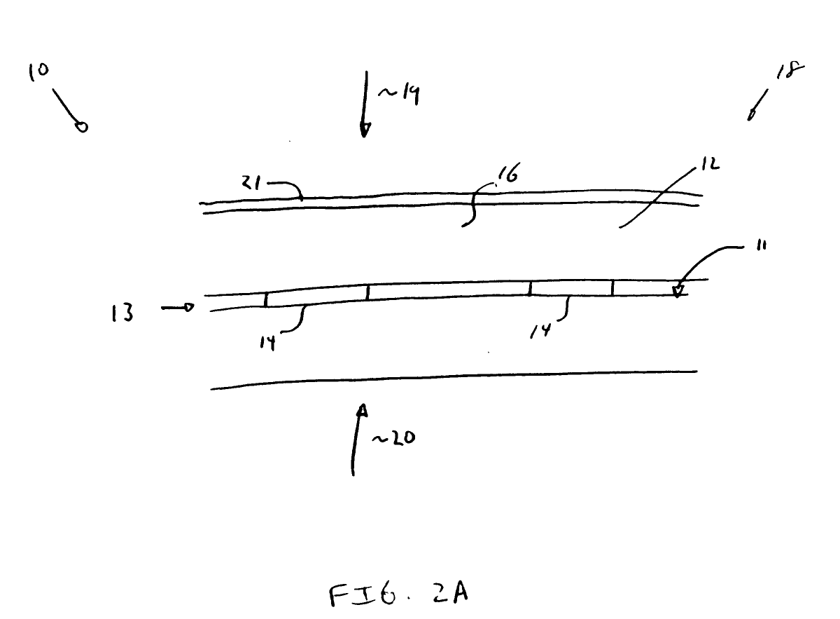

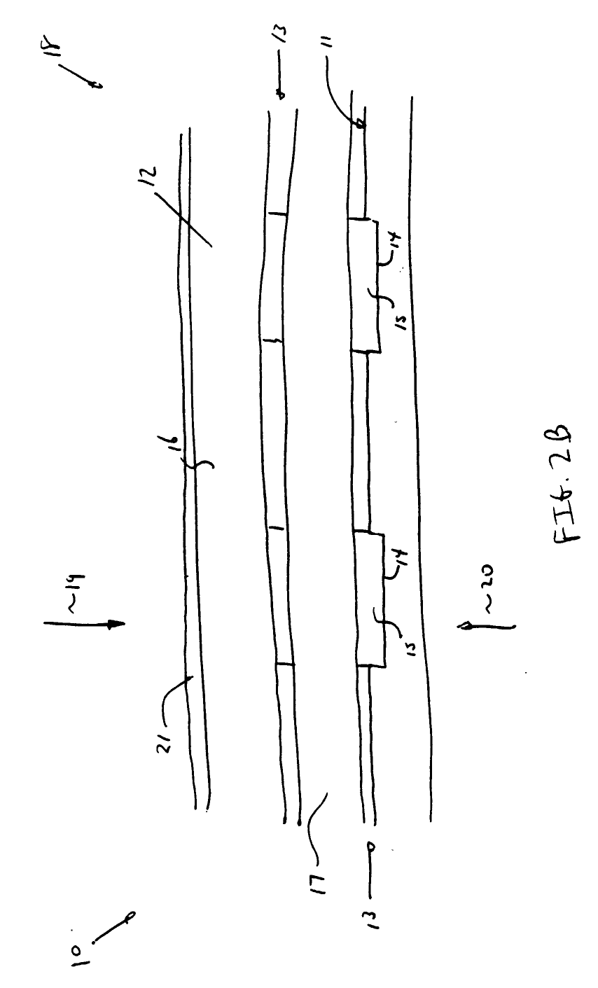

FIGS. 2a & b are cross sectional views of two exemplary bonded polymer articles. Article 10 includes a polymer 50 having a surface 11, a sonic device 12, and an adhesive 13 that is cured to form a bond between the sonic device 12 and the surface 11 of the polymer 50.

The polymer 50 has at least one bonding portion 14 on the surface 11. The adhesive 13 is disposed between the bonding portion 14 and the sonic device 12 when the sonic device 12 is disposed onto surface 11. The surface 11 can be planer, concave, convex, or any shape capable of forming a bond with the sonic device 12. In one embodiment, the surface 11 is a planer layer or block of polymer 50. In another embodiment, the surface 11 has a complex geometry, for example, a semiconductor processing apparatus. In one particular embodiment, the surface 11 also includes a recess 15 wherein the bonding portion 14 is located, as shown in FIG. 2b.

The polymer 50 is comprised of fluoropolymers or polyolefins that have low adhesion to other materials. For example, the polymer 50 can comprise polytetrafluoroethylene, perfluoroalkoxy, fluorinated ethylene propylene, TFM (fluoroloy-T), ethylene tetrafluoroethylene (Tefzel), CTFE (Kel-F) polychlorotrifluoroethylene, ECTFE (Halar) ethylene-chlorotrifluoroethylene, PVDF(Kynar) polyvinylidine fluoride, polypropylene, or polyethylene, or combinations thereof. Preferably, the surface 11 is composed of polytetrafluoroethylene, i.e., Teflon®.

Sonic device 12 is any conventional sonic energy source, for example, a sonic transducer. Device 25 produces sonic energy or is a conduit for the transmission of sonic energy to the surface 11. The device can be a crystalline material, a metal, or both. The crystalline materials include any conventionally used crystalline material, for example, sapphire, ceramic, quartz, silicon carbide, and diamond. The metals include any conventional metal, for example, aluminum, stainless steel, titanium, or manganese. Preferably, the metal is aluminum. Preferably, the device 25 is a sonic transducer composed at least in part of a crystalline material.

Adhesive 13 is any conventional epoxy resin that is cured to form a durable solid. Adhesive 13 permits the transmission and reception of energy from surface 11 to sonic device 12. Adhesive 13 adds rigidity to the article when the adhesive is cured. Preferably, adhesive 13 is capable of being used with materials having different thermal coefficients of expansion. Epoxy resins can be used and are commercially available under various trade names. Preferably, when a crystalline material is bonded to the polymer surface the adhesive is preferably EP21TDCHT available from Master Bond, Inc. Epoxy. Preferably, when a metal is bonded to the polymer surface the adhesive is preferably EP21HDCHT available from Master Bond, Inc. Epoxy.

Referring to FIG. 2a to illustrate a preferred method, at least a portion of the surface 11 that is to be bonded by contact with the adhesive 13 is contacted with an etching agent. Etching is accomplished by conventional methods, for example, immersing the bonding portion 14 in a solution containing an etching agent. Other methods of applying the etching agent include spreading or wiping the agent in the desired area. Without being bound by any theory, it is believed that the etching step chemically alters the surface of the polymer. For example, when the polymer is a fluoropolymer, it is believed that the etching agent removes fluorine atoms from the fluoropolymer surface 11 thereby providing a surface that reacts more effectively with the adhesive 13.

The etching agent is any conventional polymer etchant that prepares the polymer surface 11 for contact with the adhesive 13. Preferably, the polymer is a fluoropolymer and the etching agent is a sodium naphthalene-based etchant. Sodium naphthalene-based etchants are commercially available under different trademark names. For example, FluoroEtch® available from Acton Technologies, TETRA ETCH available from WL Gore. Other generic etching agents are available from Saint Gobain Polymers. Surface 11 is treated under conventional etching conditions that are known to those skilled in the art.

After at least the bonding portion 14 of the surface 11 of the fluropolymer 50 is chemically treated, at least a portion of the sonic device 12, such as a crystalline material, and at least a portion of surface 11 are treated with a washing solution. Washing is accomplished by conventional methods, for example, immersion, wiping, or spraying techniques. The washing solution removes any residual etching agents remaining after the etching step and prepares the fluoropolymer surface 11 for contact with the adhesive 13. A substantial number of undesirable particles adhered to surface 11 are also removed by the washing solution. The washing solution is any conventional washing solution, for example, water, IPA, or acetone. Preferably, the washing solution is water or IPA and the washing step is performed under a vacuum hood.

After the sonic device 12 and the fluoropolymer surface 11 are washed, an amount of the adhesive 13 is placed between the bonding portion 14 and the sonic device 12 to join the surface 11 and the sonic device 12. The adhesive 13 has a thickness of from about 1 mils to about 250 mils. Preferably, the adhesive 13 has a thickness of from about 5 mils to about 7 mils. In one embodiment, the adhesive 13 is applied to both the sonic device 12 and to the bonding portion 14 prior to forming the article 10. The layer of adhesive 13 disposed on the bonding portion 14 and the sonic device 12 can have a thickness of about 3 mils; thus, the total thickness of the adhesive 13 is about 6 mils. Alternatively, for example, the adhesive 13 can be applied to the bonding portion 14 or to the sonic device 12.

As shown in FIGS. 2A and 2B, the adhesive 13 is used to bond the sonic device 12, 16, & 17 at selected portions of their respective surfaces, however, the adhesive 13 can also be used to form a continuous layer between two opposing surfaces.

After forming the article 10, the adhesive 13 is cured to form a substantially permanent bond. Pressure is applied to the article 10 during the curing step in the direction of arrows 19 & 20. Any conventional method of applying pressure can be implemented, for example, clamps can compress the article 10 or the article 10 can be disposed on a planer surface and weights can be disposed on the article 10 to provide de-localized pressure. When pressure is applied to article 10, a portion of adhesive 13 disposed between the surface 11 and the sonic device 12 is pressed out from between the two surfaces. This portion of adhesive 13 is removed by conventional methods that do not damage the polymer surface 11, such as for example, by machining.

The adhesive 13 will cure over time, for example up to 72 hours. Preferably, the adhesive 13 is cured by heating it to from about 100° Fahrenheit to about 250° Fahrenheit for from about 15 minutes to about 10 hours. More preferably the adhesive 13 is cured by heating it to from about 140° Fahrenheit to about 165° Fahrenheit for from about 2 to about 10 hours.

Referring to FIG. 2B to illustrate another method of the present invention, the polymer surface 11 is bonded with a sonic device 12 that consists of a metal 17 and/or a crystalline material 16. Preferably, a layer of metal 17 is adhered to the polymer surface 11 and the device 12 is adhered to the layer of metal 17.

In the embodiment depicted in FIG. 2B, polymers are bonded with sonic devices 12 by first etching the polymer surface 11 as described above. Then the polymer surface 11 and the surface of the metal 17 are washed as described above. After the washing step, the metal 17 and the polymer surface 11 are joined by disposing the adhesive 13 between them. Preferably, the adhesive 13 is EP21TDCHT available from Master Bond, Inc. Next, the device 12 and the metal layer 17 are joined by disposing the adhesive 13 between them to form the article 10. Preferably, the adhesive 13 is EP21TDCHT available from Master Bond, Inc. Lastly, the adhesive 13 is cured to form the polymer article 10 as described above.

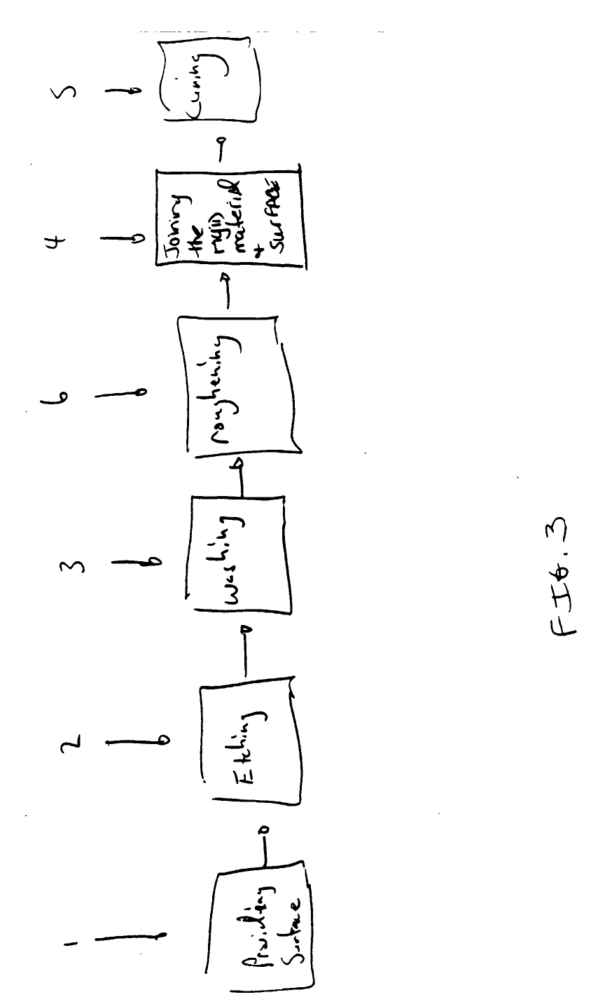

FIG. 3 is a flow chart illustrating another method of fabricating polymer articles. Referring to FIG. 3, the methods of the present invention also include a roughening step 3A to roughening the surface of the bonding portion 14 prior to applying adhesive 13 as described above. The bonding portion 14 is roughened to increase its surface area and thereby increases bond strength and longevity of the bond. Bond strength and bond longevity are generally proportional to the surface area of a bonding surface. The bonding portion 14 is preferably roughened so that it has a roughness of from about 100 to about 500 RMS, more preferably between 200-300 rms and most preferably 250 rms. The roughening step is accomplished by any conventional roughening techniques known to those skilled in the art, for example, milling with a flycutter machine or chemical surface milling.

In embodiments that include a metal layer 17, it is preferred that the metal layer 17 is roughened prior to applying the adhesive as described above. The metal plate is roughened by the same methods described for polymer surface 11 described above. The metal 17 has a roughness similar to the roughness of the bonding portion 14 described previously. After being roughened, the metal layer 17 is cleaned prior to being contacted with adhesive 13.

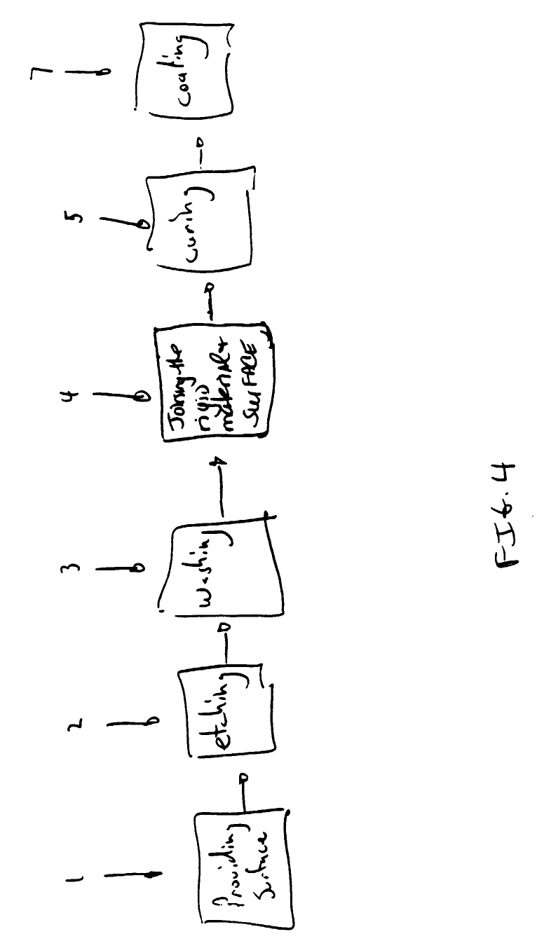

FIG. 4 is a flow chart illustrating another method of fabricating polymer articles. Referring to FIG. 4, the methods of the present invention also include a coating step 6 to coat polymer article 10 with a thermo-conductive polymer layer 21 (FIG. 2B) after the curing step 5. Thermo-conductive polymer layer 21 is used to increase heat dissipation away from article 10. The thermo-conductive polymer can be any convention polymer that dissipates undesirable quantities of heat away from the article 10, for example, epoxy based polymers.

The present invention also includes semiconductor processing apparatus and methods of making the same. The methods of the present invention provide several beneficial advantages, such as, for example, enabling sonic transducers to be bonded to layers of fluoropolymer. This enables semiconductor processing apparatus to be made from fluoropolymers and withstand the rigors of pressure and temperature common to semiconductor fabrication techniques. The present methods also overcome the disadvantages of conventional coating techniques because they can be used to make apparatus having complex geometrical shapes.

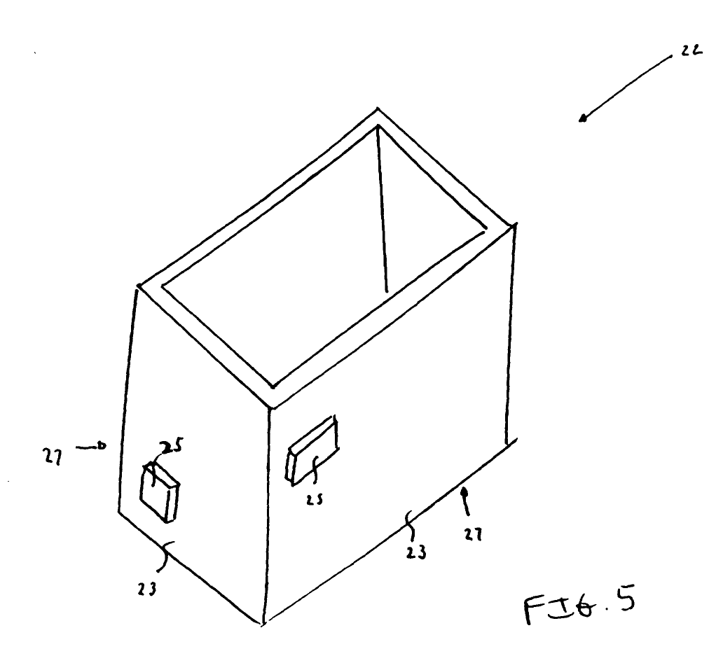

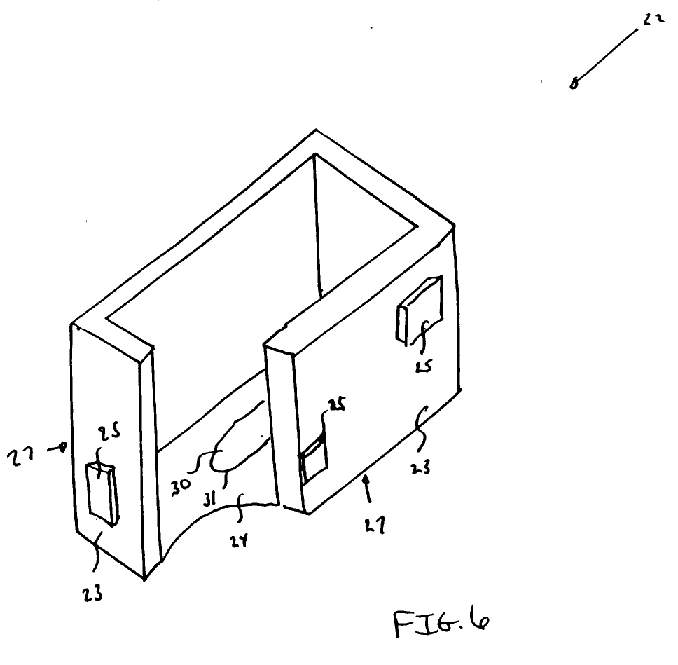

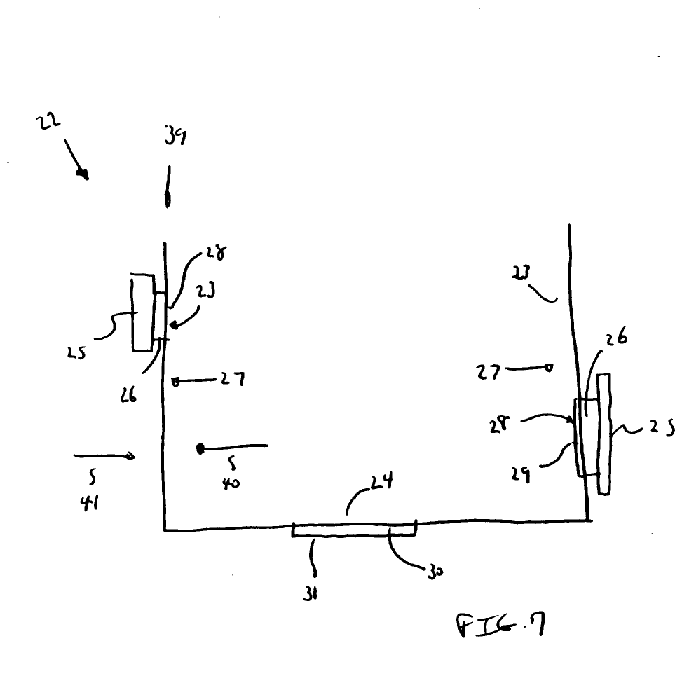

FIG. 5 is a perspective view of an exemplary semiconductor processing apparatus. FIG. 6 is a cut-away view of an exemplary semiconductor processing apparatus. FIG. 7 is a cross sectional view of an exemplary semiconductor processing apparatus. Referring to FIGS. 5, 6, & 7, apparatus 22 includes a plurality of walls 23, a bottom 24, at least one device 25, and an adhesive 26. The apparatus 22 provide intimate coupling between the device 25 and the walls 23 and therefore permits the efficient transmission of energy through the walls 23 without introducing the risk of seal failures. In one embodiment, a semiconductor processing apparatus has four walls 23, and a bottom 24.

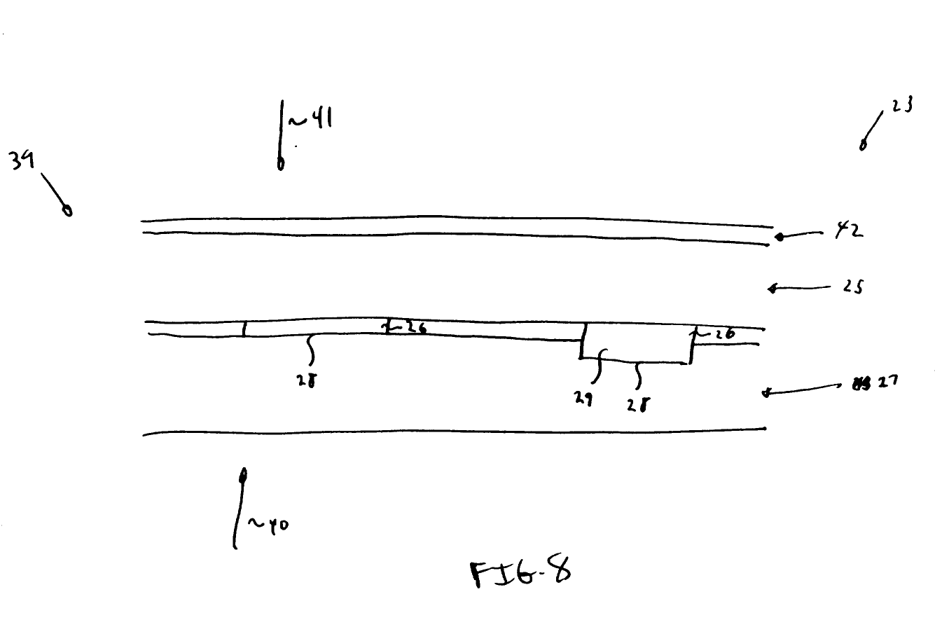

FIGS. 8 & 9 are cross sectional views of exemplary walls. Referring to FIGS. 8 & 9, at least one wall 23 comprises a polymer layer 27 having a bonding portion 28. In some embodiments, the bonding portion 28 also includes a recess 29 wherein the bonding portion is located. Polymer layer 27 is comprised of fluoropolymers or polyolefins that have low adhesion to other materials. For example, polymer layer 27 can comprise polytetrafluoroethylene, perfluoroalkoxy, fluorinated ethylene propylene, modified polytetrafluoroethylene, ethylene tetrafluoroethylene (Tefzel), CTFE (Kel-F) polychlorotrifluoroethylene, ECTFE (Halar) ethylene-chlorotrifluoroethylene, PVDF(Kynar) polyvinylidine fluoride, polypropylene, or polyethylene, or combinations thereof. Modified-PTFE includes TFM (fluoroloy-T) available from Dyneon and NXT available from DuPont. Apparatus having polymer walls have beneficial properties, such as for example, reducing the quantity of heat transmitted to fluids disposed in the vessel, increasing system reliability, and reducing the cost of processing. Preferably, the polymer layer 27 is composed of fluoropolymers. More preferably the polymer layer is composed of polytetrafluoroethylene, i.e. Teflon®.

The bottom 24 may comprises a conventional material or polymer layer 27. In one embodiment, the bottom 24 includes an aperture 30 and an aperture cover 31 that can be positioned between an open and closed position. The aperture 30 is used to flush the contents of apparatus 22. In the open position, the aperture cover 31 does not seal the aperture 30 thereby permitting fluid to pass through the aperture 30. In the closed position, the aperture 30 is fluidly sealed thereby preventing fluid flow through the aperture 30.

The device 25 includes sonic energy sources similar to the sonic device 12 described previously. Preferably, the device 25 is a sonic transducer composed at least in part of a crystalline material.

The adhesive 26 is any conventional epoxy resin and is similar to the adhesive 13 described previously. Preferably, the epoxy resin is EP21TDCHT. Adhesive 26 provides an efficient transfer of energy from the device 25 to fluids disposed in the apparatus 22. Likewise, the improved interface between the device 31 and processing solutions disposed in the apparatus 22 increases the sensitivity of the devices 25 and thereby increases their operational lifetime.

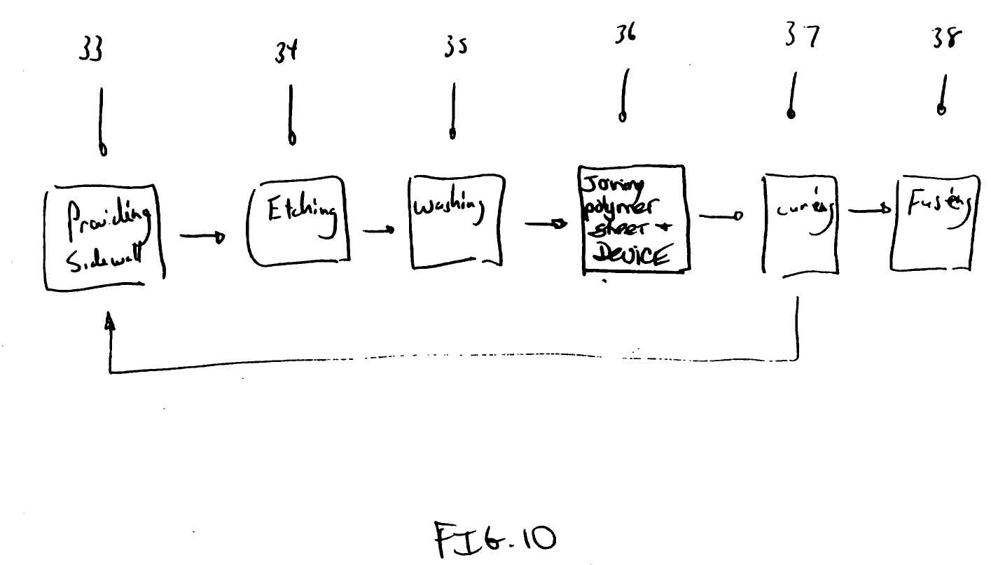

FIG. 10 is a flow chart illustrating methods of fabricating semiconductor processing apparatus. Reference numerals 33 through 38 are employed to indicate the steps of the present methods. First, a plurality of walls and a bottom are fabricated in step 33. Each wall and bottom is fabricated by first etching at least a portion of a polymer layer to provide a bonding portion in step 34. After etching, a device and the polymer layer are treated with a washing solution in step 35. Next, the device is placed onto the fluoropolymer layer and an adhesive is disposed between the bonded portion and the device in step 36. Then, the adhesive is cured in step 37. These steps are repeated as needed to fabricate the bottom and the number of walls and bottom that are needed. Lastly, the walls are fused together to make an apparatus in step 38.

Referring to FIGS. 7, 8, & 9 to illustrate methods of the present invention, bonding potion 28 of each wall is contacted with an etching agent. Etching is accomplished by conventional methods, for example, immersing bonding portion 28 in a bath containing an etched solution containing an etching agent. The etching step removes a thin layer of polymer and a substantial number of undesirable particulates from the surface of the polymer layer 27 as described previously.

In some embodiments the walls are composed of a fluoropolymer and the etching agent is any conventional fluoropolymer etchant, for example, sodium naphthalene based etchants as described previously.

After the bonding portion 28 is etched, the device 25 and the polymer layer 27 are treated with a washing solution. The washing solution removes a substantial number of particulates remaining after the etching step and prepares the polymer layer 27 for contact with the adhesive 26. Washing is accomplished by conventional methods, for example, immersion, wiping, or spraying techniques.

After the device 25 and the polymer layer 27 are washed, a layer of adhesive 26 is disposed between the bonding portion 28 and the device 25. The device 25 is then disposed on the polymer layer 27 to form a wall 23. The adhesive layer 26 is applied and has a thickness described previously.

After forming the wall 23, the adhesive 26 is cured to form a substantially permanent bond. Preferably, pressure is applied to the apparatus 22 during the curing step in the direction of arrows 40 & 41, and curing is conducted as described previously.

After the walls 23 are fabricated, the walls are fused together by conventional polymer fusion techniques, for example, thermowelding. When the walls 23 are fused together the interior surface of the apparatus is continuously sealed. Sonic devices can be disposed on any surface of the apparatus, for example, the exterior surface of the walls or the interior surface of the walls. In some embodiments, the apparatus 22 includes a bottom or a top. The sonic device 25 can also be adhered to the bottom interior or exterior surfaces, or the top interior or exterior surfaces.

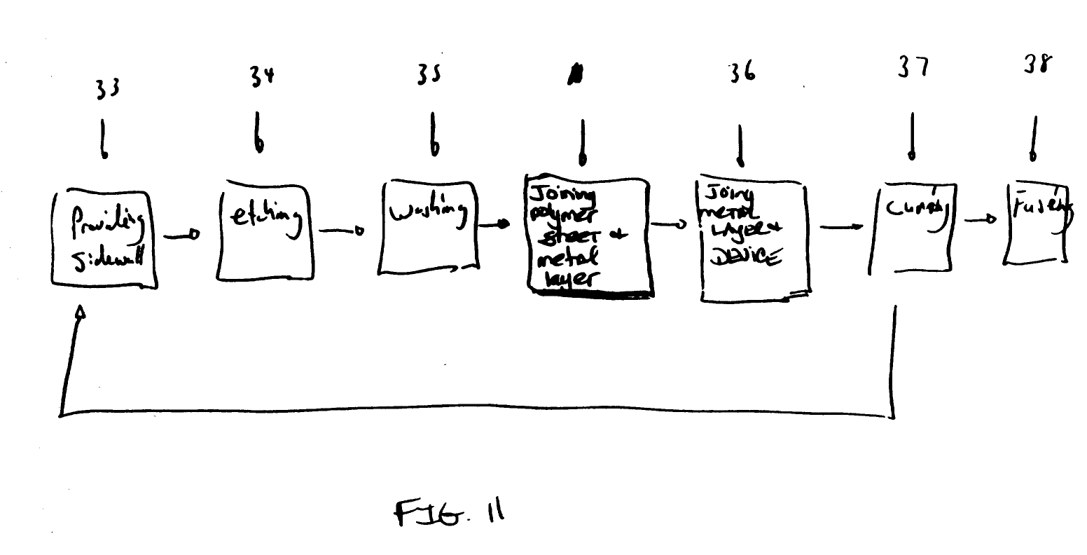

FIG. 11 is a flow chart illustrating another method of fabricating semiconductor processing apparatus. Referring to FIG. 7, each wall of the apparatus 22 is fabricated by bonding a metal 17, a device 25, or both to a polymer layer 27. In one embodiment, a layer of metal 17 is adhered to a layer of fluoropolymer 27 as shown by step 36A. Then device 25 is adhered to the layer of metal 17 as shown by step 36. Metals 17 are added for several beneficial purposes. For example, adding a layer of metal 17 increases heat dissipation from polymer layer 27. Metal 17 also provides rigidity to the fluoropolymer article to reduce stresses that could cause highly sensitive device to crack or break, such as for example, a crystalline sonic transducer. Metal layer 17 also helps resonate sonic energy emitted from device 25.

In this embodiment, a semiconductor wafer treatment vessel is fabricated by first etching polymer layer 27 as described above. The polymer layer 27 and a layer of metal 17 are washed as described above. After the washing step, metal layer 17 and polymer layer 27 are joined by disposing a layer of adhesive 26 between them. Preferably, adhesive 26 is epoxy resin EP21AOHTLV. Next, device 25 is joined with metal layer 17 by disposing a layer of adhesive 26 between them to form apparatus 22. Adhesive 26 is then cured as described above.

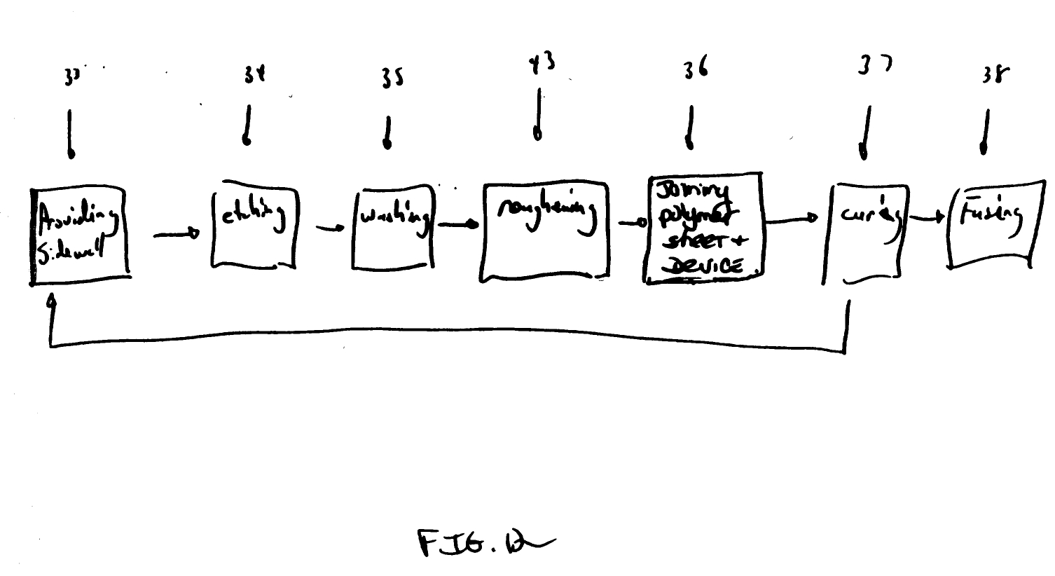

FIG. 12 is a flow chart illustrating another method of fabricating semiconductor processing apparatus. Referring to FIGS. 8 & 12 the methods of the present invention also include an additional roughening step 43 to roughen the surface of bonding portion 28 prior to applying the adhesive 26 in step 36 as described above. Bonding portion 28 is roughened in step 43 to increase its surface area and thereby increases bond strength and longevity of the bond. Bond strength and bond longevity are substantially proportional to the surface area of bonding portion 28. Bonding portion 28 is roughened to a roughness of from about 100 to about 500 RMS, more preferably from 200 to 300 RMS, and most preferably around 250 RMS. The roughening step is accomplished by any conventional roughening techniques known to those skilled in the art, for example, milling with a flycutter machine or with chemical roughening.

In embodiments that include a metal layer 17, it is preferred that the metal layer 17 is roughened prior to applying the adhesive as described above. The metal plate is roughened by the same methods described for the bonding portion 28 described above. The metal 17 has a roughness similar to the roughness of the bonding portion 28 described previously. After being roughened, the metal layer 17 is cleaned prior to being contacted with adhesive 26.

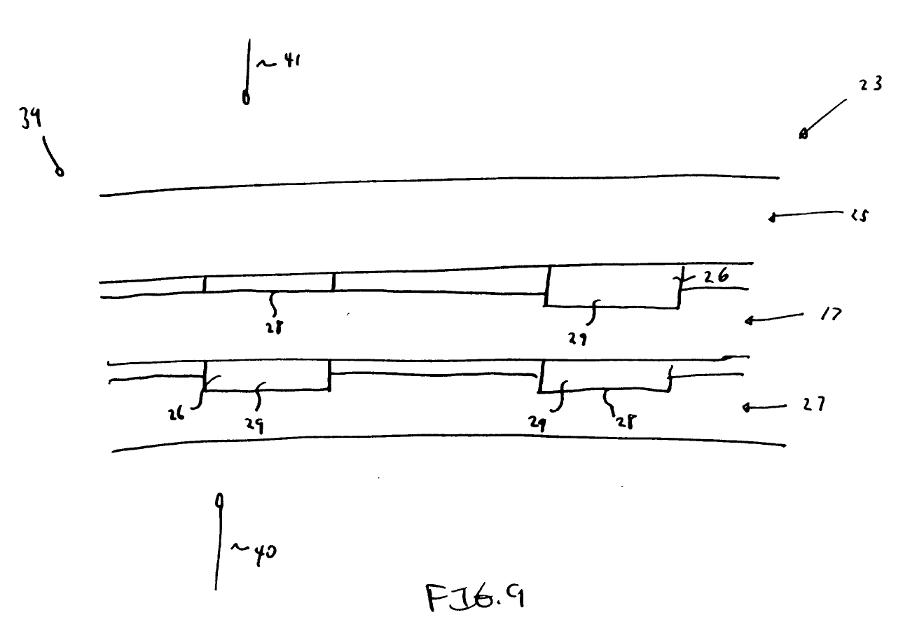

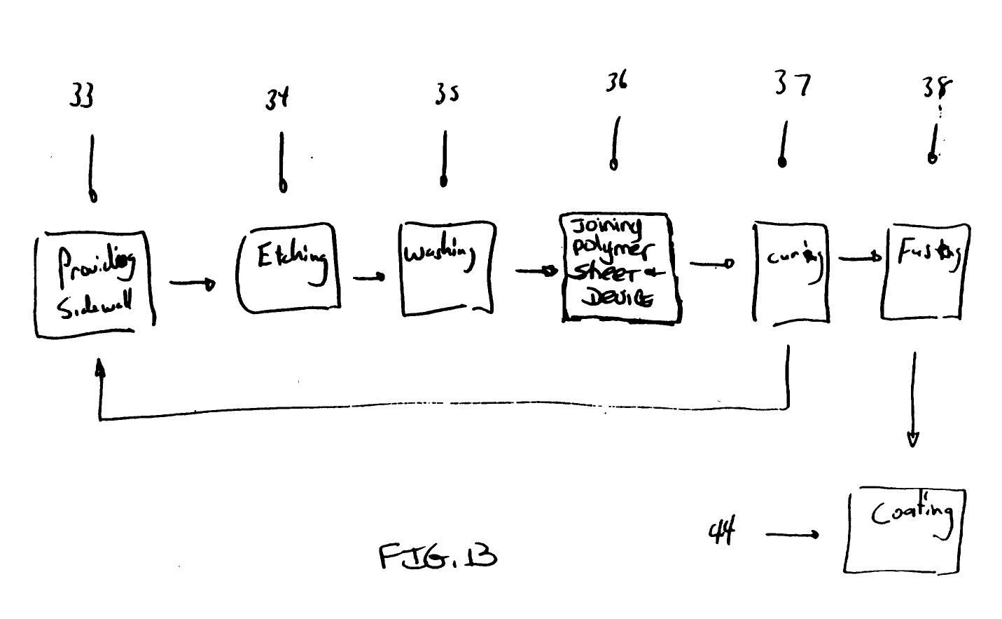

FIG. 13 is a flow chart illustrating another method of fabricating semiconductor wafer treatment vessels. Referring to FIGS. 9 & 13, the methods of the present invention also include an additional coating step 44 to coat the apparatus 22 with a thermo-conductive polymer layer 42 after the adhesive 26 is cured. The thermo-conductive polymer 42 can be any conventional polymer that dissipates undesirable quantities of heat away from the apparatus 22, such as for example, epoxy resins.

In another embodiment, the semiconductor processing apparatus comprising sapphire, ceramic, quartz, silicon carbide, diamond, or polyolefins that have low adhesion to other materials. A sonic device 25 is adhered to at least one wall by an epoxy resin as described above.

In another embodiment, the semiconductor processing apparatus are formed from one or more solid blocks or billets of material. Conventional machining techniques are employed to shape the semiconductor processing apparatus. The solid block or billet of material is, for example, a polymer material such as a flouropolymer. The block of material is shaped by machining techniques to form a recess or chamber in which to process one or more semiconductor devices. The chamber formed can be any shape known to those skilled in the art. If the semiconductor processing apparatus contains one or more metal materials, these materials may also be shaped by machining techniques.

In another embodiment, a method and apparatus is disclosed for single wafer processing that applies a cleaning or rinse solution to one or both sides of a wafer positioned above an apparatus. See U.S. patent application Ser. No. 09/891,849, published as U.S. patent application Publication No. 20020029788, which is herein incorporated by reference in its entirety.

The wafer can be positioned in a bracket, the bracket rotated, and the apparatus can apply megasonic energy in the form of one or more frequencies to a side of the wafer. The bracket can hold the wafer at three or more points where wafer position is maintained by gravity. At least one frequency applied to a 300 mm wafer can be at 5.4 MHz. The wafer side facing the apparatus may be the non-device side, and the platter can generate the megasonic energy at one or more frequencies with one or more acoustic wave transducers positioned on the platter backside.

The frequencies selected may be un-reflected by the apparatus and the wafer such that a large percentage of the megasonic energy will reach the wafer side not facing the apparatus. While a cleaning/rinse solution is applied to the wafer non-device side, a second cleaning/rinse solution may be applied to the wafer device side. The megasonic energy may be pulsed and/or applied at varying power.

Those skilled in the art will appreciate that numerous changes and modifications may be made to the embodiments described herein, and that such changes and modifications may be made without departing from the spirit of the invention.

What is claimed is:

1. A method for adhering a sonic device to a polymer surface comprising the steps of:
providing a polymer surface having a bonded portion that is to be adhered to a sonic device, wherein the polymer is a fluoropolymer, polyethylene, polypropylene, or combination thereof;
etching at least a portion of the bonded portion with an etching agent;
treating the sonic device and the etched portion of the bonded portion with a washing solution;
bringing the sonic device and the bonded portion of the polymer surface together, wherein an adhesive is applied in between the bonded portion of the polymer surface and the sonic device; and
curing the adhesive.

2. The method of claim 1 wherein the adhesive is applied to the bonding portion.

3. The method of claim 1 further comprising the step of roughing the surface of the bonding portion to a roughness from about 250 to about 500 RMS, said roughing step occurring before the adhesive is applied.

4. The method of claim 1 further comprising the step of coating the sonic device and polymer surface in a thermo-conductive polymer after the adhesive is cured.

5. The method of claim 1 further comprising the step of machining the polymer surface to form a recess before the etching step, said bonding portion located within the recess.

6. The method of claim 1 wherein the sonic device comprises a crystalline material.

7. The method of claim 6 wherein a layer of metal is adhered to the polymer surface and a sonic device is adhered to the layer of metal.

8. The method of claim 7, wherein the metal is aluminum, stainless steel, titanium, or manganese.

9. The method of claim 1 wherein the sonic device is a sonic transducer.

10. The method of claim 1, wherein the polymer comprises fluoropolymers.

11. The method of claim 1, wherein the polymer is polytetrafluoroethylene, perfluoroalkoxy, fluorinated ethylene propylene, modified polytetrafluoroethylene, ethylene tetrafluoroethylene, CTFE polychlorotrifluoroethylene, ECTFE ethylene-chlorotrifluoroethylene, PVDF polyvinylidine fluoride, polypropylene, and polyethylene.

12. A semiconductor processing apparatus comprising:
a wall comprising a polymer and having a bonded portion;
a bottom comprising a polymer;
at least one sonic device adhered to the bonding portion of the wall; and
an adhesive disposed between the sonic device and the bonding portion of the wall.

13. The apparatus of claim 12 wherein the wall further comprises a layer of metal.

14. The apparatus of claim 13 wherein the layer of metal is adhered to the polymer surface and the sonic device is adhered to the layer of metal.

15. The apparatus of claim 12 wherein the polymer comprises fluoropolymers.

16. The apparatus of claim 12 wherein the polymer comprises polytetrafluoroethylene, perfluoroalkoxy, fluorinated ethylene propylene, modified polytetrafluoroethylene, ethylene tetrafluoroethylene, CTFE polychlorotrifluoroethylene, ECTFE ethylene-chlorotrifluoroethylene, PVDF polyvinylidine fluoride, polypropylene, and polyethylene.

17. The apparatus of claim 12 wherein the metal is aluminum, stainless steel, titanium, or manganese.

18. The apparatus of claim 12 wherein the sonic device is a sonic transducer.

19. A method for fabricating a semiconductor processing apparatus comprising the steps of:
fabricating a plurality of walls, wherein one or more walls have a bonded portion, a wall made by:
providing a polymer layer;
etching at least a portion of the bonded portion with an etching agent;
treating a sonic device and the etched portion of the bonded portion with a washing solution;
bringing the sonic device and the bonded portion of the polymer layer together, wherein an adhesive is applied in between the bonded portion of the polymer layer and the sonic device; and
curing the adhesive; and
fusing the walls together to make an apparatus.

20. The method of claim 19 further comprising the step of bonding a layer of metal to the polymer layer.

21. The method of claim 20 wherein a layer of metal is adhered to the polymer layer and a sonic device is adhered to the layer of metal.

22. The method of claim 19 wherein the polymer layer comprises fluoropolymers.

23. The method of claim 19 wherein the polymer layer comprises polytetrafluoroethylene, perfluoroalkoxy, fluorinated ethylene propylene, modified polytetrafluoroethylene, ethylene tetrafluoroethylene, CTFE polychlorotrifluoroethylene, ECTFE ethylene-chlorotrifluoroethylene, PVDF polyvinylidine fluoride, polypropylene, and polyethylene.

24. The method of claim 19 wherein the metal is aluminum, stainless steel, titanium, or manganese.

25. The method of claim 19 wherein the sonic device is a sonic transducer.

26. The method of claim 19 wherein the sonic device comprises a crystalline material.

27. A method for fabricating a semiconductor processing apparatus comprising the steps of:
shaping one or more blocks of material to form a chamber, said chamber having at least one bonded portion;
forming one or more etched portions by etching at least a portion of a bonded portion with an etching agent;
treating one or more sonic devices and an etched portion with a washing solution;
bringing a sonic device and a bonded portions together, wherein an adhesive is applied between a bonded portion and a sonic device; and
curing the adhesive.
